(19) United States
(12) Patent Application Publication
(10) Pub. No.: US 2023/0389134 A1
(43) Pub. Date: Nov. 30, 2023

(54) METHODS OF MAKING HEATING BLOCKS, HEATING BLOCKS, AND SEMICONDUCTOR PROCESSING SYSTEMS HAVING HEATING BLOCKS

(71) Applicant: ASM IP Holding B.V., Almere (NL)

(72) Inventors: ChangMin Lee, Hwaseong-si (KR); Joaquin Aguilar Santillan, Gilbert, AZ (US); Nobuaki Tanabe, Kawasaki-shi (JP); Hong Gao, San Jose, CA (US); Shanker Kuttath, Austin, TX (US)

(21) Appl. No.: 18/201,601

(22) Filed: May 24, 2023

Related U.S. Application Data
(60) Provisional application No. 63/346,467, filed on May 27, 2022.

(51) Int. Cl. H05B 3/28; C04B 35/581; C04B 35/645; C04B 37/02; H01L 21/687

(52) U.S. Cl. CPC H05B 3/283; C04B 35/581; C04B 35/645; C04B 37/023; H01L 21/68757; C04B 2235/3865; C04B 2235/3206; C04B 2235/3222; C04B 2235/612; C04B 2237/366; C04B 2237/40; C04B 2237/80; H05B 2203/016; H05B 2203/017

(57) ABSTRACT

A method of manufacturing a heating block includes a first step of providing a ceramic material to a mold, a second step of sintering the ceramic material and forming a plate, and a third step of machining the plate. A shaft is connected to the plate in a fourth step, and rods are bonded to the plate in a fifth step of the method. Heating blocks and semiconductor processing systems having heating blocks are also described.

### CROSS-REFERENCE TO RELATED APPLICATIONS

This application claims priority to U.S. Provisional Patent Application Ser. No. 63/346,467 filed May 27, 2022 titled METHODS OF MAKING HEATING BLOCKS, HEATING BLOCKS, AND SEMICONDUCTOR PROCESSING SYSTEMS HAVING HEATING BLOCKS, the disclosure of which is hereby incorporated by reference in its entirety.

### FIELD OF INVENTION

The present disclosure generally relates to fabricating semiconductor devices. More particularly, the present disclosure relates to heating blocks and methods of manufacturing heating blocks to support substrates during the fabrication of semiconductor devices.

### BACKGROUND OF THE DISCLOSURE

Semiconductor devices, such as integrated circuit and power electronic semiconductor devices are commonly fabricated by depositing material layers onto substrates. Material layer deposition is generally accomplished by loading a substrate onto a heating block, heating the substrate to a desired material layer deposition material using the heating block, and flowing a material layer precursor across the substrate. As the material layer precursor flows across the substrate a material layer deposits onto the substrate, the material layer typically developing film properties corresponding to the heating of the substrate by the heating block. Once the material layer reaches a desired thickness flow of the material layer precursor ceases, the substrate is unloaded from the heating block and the substrate sent on for further processing.

In some material layer deposition processes the heating block is formed from a ceramic material, such as aluminum nitride (AlN). The ceramic material forming the heating block generally has corrosion resistance and mechanical properties suitable for the corrosive environment of the reaction chamber housing the heating block, and typically has mechanical properties to resist deformation and/or embrittlement potentially associated with certain material layer deposition processes. Employment of a ceramic material allows accessories to be embedded within the heating block, such as radio frequency electrodes, which facilitates heating the substrate using radio frequency energy. Employment of a ceramic material also allows for selection of bulk resistivity at temperatures suitable for material layer deposition that enable electrostatic chucking of the substrate, which facilitates loading and unloading of substrates from the heating block.

One challenge to forming heating blocks from ceramic materials is yield of the process used to manufacture heating blocks. For example, as shown in FIG. 1A, some heating blocks may exhibit swelling during manufacture, potentially rendering the heating block unsuitable for use. As shown in FIG. 1B, some heating blocks may exhibit blistering during the manufacturing process, such as around embedded accessories like RF coils and/or heating elements, also potentially rendering the heating block unsuitable for use. And some heating blocks may exhibit cracking—either during the manufacturing process or during service—also rendering the heating block unsuitable for supporting substrates during the fabrication of semiconductor devices. Without being bound by a particular theory or mode of operation, applicants have come to understand the cause of such producibility difficulty to arise from a need to more close control certain parameters of the manufacturing process employed to fabricate heating blocks using ceramic materials, such as aluminum nitride.

Such heating blocks and methods of manufacturing heating blocks have generally been acceptable for their intended purpose. However, there remains a need in the art for improved methods of manufacturing heating blocks for semiconductor processing systems, heating blocks, and semiconductor processing systems including such heating blocks. The present disclosure provides a solution to this need.

### SUMMARY OF THE DISCLOSURE

A method of manufacturing a heating block is provided. The method includes a first step of providing a ceramic material to a mold, a second step of sintering the ceramic material and forming a plate, and a third step of machining the plate. A shaft is connected to the plate in a fourth step, and rods are bonded to the plate in a fourth step.

In addition to one or more of the features described above, or as an alternative, further examples of the method may include that the second step of sintering the ceramic material and forming a plate further includes a first sub-step of heating the ceramic material to a first temperature, a second sub-step of further heating the ceramic material to a second temperature, and a third sub-step of maintaining the second temperature. The plate is cooled to the first temperature in a fourth sub-step, and the plate cooled to the second temperature in a fifth sub-step. A pressure is applied to the ceramic material to a set pressure during the first sub-step and maintained throughout second step through the fourth sub-step.

In addition to one or more of the features described above, or as an alternative, further examples of the method may include that the set pressure is between about 75 megapascals (10900 pounds per square inch) and about 125 megapascals (about 18000 pound square inch).

In addition to one or more of the features described above, or as an alternative, further examples of the method may include that the cooling rate in the fourth sub-step is between about 1 degree Celsius (34 degrees Fahrenheit) per second and about 5 degrees Celsius (40 degrees Fahrenheit) per second.

In addition to one or more of the features described above, or as an alternative, further examples of the method may include that the first temperature is between about 800 degrees Celsius (1500 degrees Fahrenheit) and about 1000 degrees Celsius (1800 degrees Fahrenheit).

In addition to one or more of the features described above, or as an alternative, further examples of the method may include that the second temperature is between about 1500 degrees Celsius (2700 degrees Fahrenheit) and about 2000 degrees Celsius (3600 degrees Fahrenheit).

In addition to one or more of the features described above, or as an alternative, further examples of the method may include that the second temperature is maintained for more than 36 hours during the third sub-step.

In addition to one or more of the features described above, or as an alternative, further examples of the method may include that the ceramic material is at least one of aluminum nitride (AlN), boron nitride (BN), silicon nitride (SiN) and silicon carbide (SiC).

In addition to one or more of the features described above, or as an alternative, further examples of the method may include that the ceramic material comprises one or more additive, and that the one or more additive comprises less than about 1% of the ceramic material by mass.

In addition to one or more of the features described above, or as an alternative, further examples of the method may include that the one or more additive comprises at least one of magnesium oxide (MgO) and aluminum magnesium oxide (Al₂MgO₄).

In addition to one or more of the features described above, or as an alternative, further examples of the method may include that the shaft comprises a cylinder with hollow inner space, and that the shaft supports the plate.

In addition to one or more of the features described above, or as an alternative, further examples of the method may include embedding a heating element and an electrode within the ceramic material.

In addition to one or more of the features described above, or as an alternative, further examples of the method may include that the third step of machining the plate imparts a flatness into the plate between about 20 microns (0.0008 inches) and about 50 microns (0.002 inches).

In addition to one or more of the features described above, or as an alternative, further examples of the method may include the fifth step includes connecting a power rod to the heating element and connecting the power rod to the electrode.

In addition to one or more of the features described above, or as an alternative, further examples of the method may include that the connecting is carried out by at least one of brazing, welding and soldering.

In addition to one or more of the features described above, or as an alternative, further examples of the method may include that the sintering is at least one of solid-phase sintering and liquid-phase sintering, or both solid-phase sintering and liquid-phase sintering.

A heating block is provided. The heating block is manufactured using the method as described above.

In addition to one or more of the features described above, or as an alternative, further examples of the heating block may include a heating element embedded within the ceramic material forming the plate, an electrode embedded within the ceramic material forming the plate, and a power rod electrically connected to the heating element and the electrode. The power rod is brazed to the heating element and the electrode. The ceramic material includes aluminum nitride (AlN) and an additive comprising comprises at least one of magnesium oxide (MgO) and aluminum magnesium oxide (Al₂MgO₄), the additive comprising less than about 1% of the ceramic material by weight.

A semiconductor processing system is provided. The semiconductor processing system includes a heating block manufactured using the method as described above.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIGS. 1A and 1B are plan and interior views of a heating block formed from a ceramic material using a hot press sintering manufacturing method, showing a swelling defect and a blister defect within the ceramic material forming the heating block;

FIG. 2 is a block diagram of a method of manufacturing a heating block, showing a step for sintering a plate from a ceramic material;

FIGS. 3A and 3B are charts of temperature and pressure during sub steps of the sintering step of FIG. 2, showing relation of temperature and pressure during sub-steps of a first sintering operation in FIG. 3A and during sub-steps of a second sintering step in FIG. 3B;

FIG. 4 is a schematic view of a sintering mechanism during the sintering step of FIG. 2, showing material migration along surfaces of ceramic particles during the sintering step;

FIG. 5 is a cross-sectional side view of a heating block manufactured using a sintering step including the sub-steps of FIG. 3B, schematically showing a heater element and a radio frequency element embedded within the bulk ceramic material forming the heating block;

FIGS. 6A and 6B are top down scanning electron microscope images of heating blocks manufactured using a sintering step including the sub-steps of FIG. 3A and a sintering step including the sub-steps of FIG. 3B, showing swelling and blistering in heating block imaged in FIG. 6A and no swelling and no blistering in the heating block imaged in FIG. 6B;

FIG. 7 is chart of thermal conductivity versus temperature in heating blocks manufactured using a sintering step having the sub-steps shown in FIG. 3A and a sintering step having sub-steps shown in FIG. 3B, showing higher thermal conductivity in the heating block manufactured using the sub-steps shown in FIG. 3B relative to thermal conductivity in the ceramic heating block manufactured using the sub-steps shown in FIG. 3A;

FIGS. 8A and 8B are graphs of silicon oxide film thickness versus rotational position on the lower surfaces of heating blocks manufactured using sintering steps having the sub-steps shown in FIG. 3A and FIG. 3B, showing that the material properties of the heating block manufactured using the sub-steps shown in FIG. 3B limit the tendency of silicon oxide film deposition in relation to the material properties of heating blocks manufactured using the sub-steps shown in FIG. 3A; and

FIG. 9 is a graph of volume resistivity versus temperature of ceramic heating blocks manufactured using sintering steps having the sub-steps shown in FIG. 3A and in FIG. 3B, showing that volume resistivity of the heating block manufactured using the sub-steps shown in FIG. 3B is greater than the volume resistivity of the heating block manufactured using the sub-steps shown in FIG. 3A within a temperature range employed for material layer deposition.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

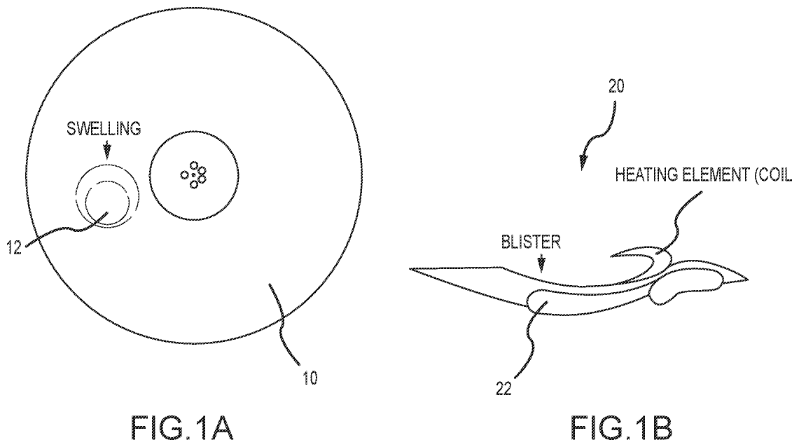

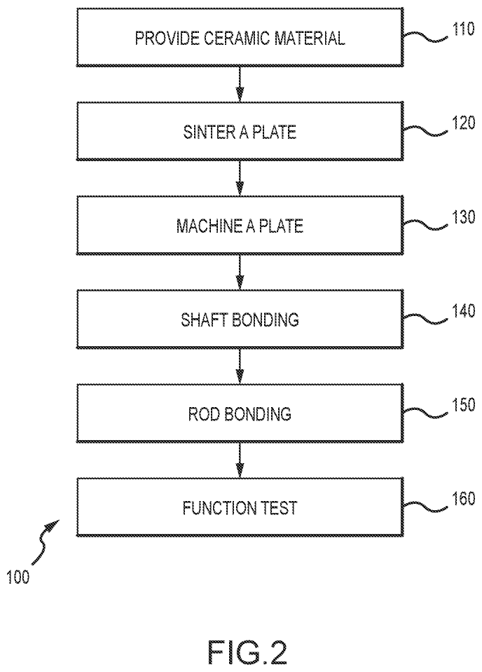

Reference will now be made to the drawings wherein like reference numerals identify similar structural features or aspects of the subject disclosure. For purposes of explanation and illustration, and not limitation, a partial view of an example of a method of manufacturing a ceramic heating block is shown in FIG. 2 and is designated generally by reference character 100. Other examples of methods of making ceramic heating blocks, ceramic heating blocks, and semiconductor processing systems having ceramic heating blocks in accordance with the present disclosure are shown in FIGS. 1 and 3-9, as will be described. The systems and methods of the present disclosure may be used to manufacture heating blocks, such as heating blocks formed from ceramics and employed to support substrates during the deposition of material layers onto the substrates using atomic layer deposition (ALD) techniques, though the present disclosure is not limited to heating blocks employed for ALD material layer deposition techniques or to heating blocks for material layer deposition in general.

With reference to FIG. 1A and FIG. 1B, a heating block 10 and a heating block 20 are shown. The heating block 10 has a swelling defect 12. The heating block 20 has blister defect 22. The present disclosure is generally relative to a manufacturing method for a heating block wherein the occurrence of the swelling defect 12 and/or the blister defect 22, as well as cracking and other mechanical properties that may be undesirable in certain material layer deposition operations, within the ceramic material forming the heating block.

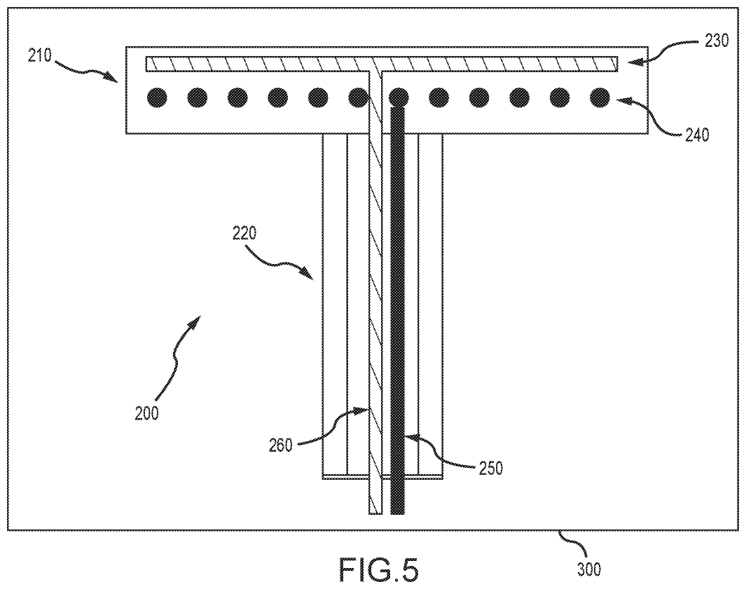

With reference to FIG. 2, a method 100 of manufacturing a heating block, e.g., a ceramic heating block 200 (shown in FIG. 5), is shown. The method 100 includes a step 110 of providing a ceramic material, a step 120 of sintering a plate from the ceramic material, and a step 130 of machining the plate 130. The method 100 also includes a step 140 of bonding a shaft to the plate, a step 150 of bonding a rod to the plate, and a step 160 of performing functional testing on the heating block.

In step 110, a ceramic material is supplied to a plate-shaped mold. The ceramic material may be at least one of aluminum nitride (AlN), boron nitride (BN), silicon nitride (SiN), and silicon carbide (SiC). The ceramic material may include an additive. In certain examples, the additive may include one or more of magnesium oxide (MgO), yttrium oxide (Y₂O₃), calcium fluoride (CaF₂), and lithium fluoride (LiF) as an additive. In accordance with certain examples, the additive may provide the technical benefit of improving volume resistivity of the heating block relative to heating blocks lacking the additive and/or having a different composition. For example, the heating block may have a volume resistivity that is between about 10e¹⁰ ohm-centimeter and about 10e¹² ohm-centimeter. The heating block may exhibit these resistivities at relatively high temperature, for example, at temperatures that are between about 400 degrees Celsius and about 650 degrees Celsius. It is also contemplated that one or more of the ceramic material and/or the additive included in the ceramic material may provide a thermal conductivity that is between about watts per milli Kelvin and about 60 watts per milli Kelvin. According to the disclosure, a plate may include a heating block body, one side of the plate may be loaded with a substrate, and the other side of the plate may be connected to a support, e.g. a shaft, that supports the plate.

In certain examples, an aluminum nitride (AlN) ceramic material forming the plate may include less than about 1% magnesium oxide (MgO) and dialuminum magnesium tetraoxide (Al₂MgO₄) as additives. The ceramic material may be provided in the form of powder or slurry. A heating element, such as a heating wire, and a radio frequency (RF) electrode for implementing an electrostatic chucking (ESC) function may be further provided, e.g., embedded, within the plate body when the ceramic material is provided. In accordance with certain examples, another device for additional function may be further provided within the heating block.

In the step 120 the ceramic material provided is sintered during a hot press sintering process. In certain examples, the hot press sintering process of step 120 may include heating the ceramic material. In accordance with certain examples, the hot press sintering process of step 120 may include pressing (e.g., applying pressure) to the ceramic material. It is also contemplated that, in accordance with certain examples, the hot press sintering process of step 120 may include both heating and pressing the ceramic material, for example, at high temperature and high pressure, to turn the ceramic material into a solid-phase plate. The sintering conditions may be precisely controlled to prevent one or more defect such as cracks, pores, blisters and swelling, from occurring within the heating block during manufacturing. Examples of sintering condition will be described in more detail afterward.

In the step 130, a surface of the plate is machined using a machining process. In certain examples, surface flatness of the plate may be improved by the machining process. For example, the surface flatness may be improved such that the surface flatness is between about 20 microns and about 55 microns. In accordance with certain examples, the machining process may eliminate (e.g., remove) a deformed portion from the plate that may develop during the sintering step 120. The improved flatness may enable a substrate (e.g., a wafer formed from a semiconductor material such as silicon) to be tightly loaded onto the heating block and enhance chucking of the substrate chucking to the heating block. The plate comprising the heating block may be prepared through the step 110 to the step 130.

In the step 140, a shaft is connected (e.g., bonded) to the plate. In certain examples, the shaft may be cylindrical in shape. The shaft may be connected to one side of the plate, e.g., to a bottom surface of the plate opposite an upper surface of the plate, to support the heating block. The shaft may be formed from the same material as the plate. In accordance with certain examples, the shaft may be define a hollow inner space within an interior of shaft. The hollow inner space defined within the shaft may receive therethrough one or more rod, e.g., a power rod and/or an electrode rod, which may connect to one or more heating element and one or more radio frequency (RF) electrode embedded within the plate. Step 140 may be carried out at a temperature that is between about 1,400 degrees Celsius and about 1,800 degrees Celsius or that is between about 1,500 degrees Celsius and about 1,700 degrees Celsius. Step 140 may be carried out during a time interval that is greater than 24 hours, for example, during a process carried out during an interval of between about 24 hours and about 48 hours.

In the step 150, one or more of a heating element and an RF electrode embedded within the plate are connected (e.g., bonded) to a power rod and/or an electrode rod. In certain examples, one or more of the power rod and the electrode rod may be connected to the heating element and/or the RF electrode with braze using a brazing process. In accordance with certain examples, one or more of the power rod and the electrode rod may be connected to the heating element and/or the RF electrode with a weld using a welding process. It is also contemplated that, in accordance with certain examples, that one or more of the power rod and the electrode rod may be connected to the heating element and/or the RF electrode with solder using a soldering process. Step 150 may be carried out at a temperature that is between 800 degrees Celsius and about 1,200 degrees Celsius. Step 150 may be carried out at a temperature that is between about 900 degrees Celsius and about 1,200 degrees Celsius. Step 150 may be carried out during an interval lasting longer that about 8 hours, for example during an interval that has a duration of between about 8 hours and about 16 hours.

In the step 160, functional testing of the heating block is accomplished. Step 160 may include a sub-step for a heating testing, wherein heating performance of the heating block is accomplished. Step 160 may include a sub-step for RF electrode testing, wherein electrical performance of the RF electrode is tested. Step 160 may include a sub-step for chucking testing, wherein the electrostatic chucking performance of the heating block is tested.

In certain examples, the method 100 may include an intermediate inspection step wherein the heating block undergoes an inspection. The intermediate inspection step may include an ultrasonic inspection, wherein the heating block is inspected using an ultrasonic technique. In certain examples, the intermediate inspection step may be carried out after the step 130. In accordance with certain examples, the step 170 may be carried out after the step 140. In further examples, the intermediate inspection step may be carried out after the step 150. It is also contemplated that, in accordance with certain examples, the intermediate inspection step may be accomplished after more than one of the step 130, the step 140, and the step 150.

In certain examples, the method 100 may include an embossing step, wherein the heating block is embossed. In this respect it is contemplated that a surface of the plate may be embossed. More specifically, an upper surface wherein a substrate is loaded may be embossed. As will be appreciated by those of skill in the art in view of the present disclosure, defining an embossed surface on the upper surface of the plate can facilitate chucking of a substrate on the upper surface of the heating block.

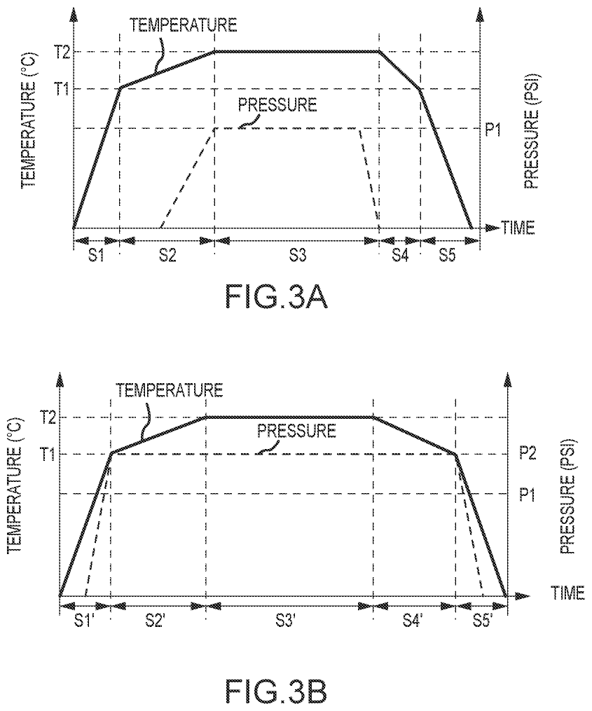

With reference to FIGS. 3A and 3B, sub-steps of the step 120 are shown according to two examples of hot-press sintering process. As shown in FIG. 3A, the step 120 may include a first sub-step S1, a second sub-step S2, and a third sub-step S3. As also shown in FIG. 3A, the hot press sintering process of step 120 may include a fourth sub-step S4 and a fifth sub-step S5. During the first sub-step S1, the ceramic material provided to the plate mold is heated to a first temperature T1. Heating the ceramic material provided to the plate mold may include heating the ceramic material to a first temperature T1 that is between about 800 degrees Celsius and about 1,000 degrees Celsius.

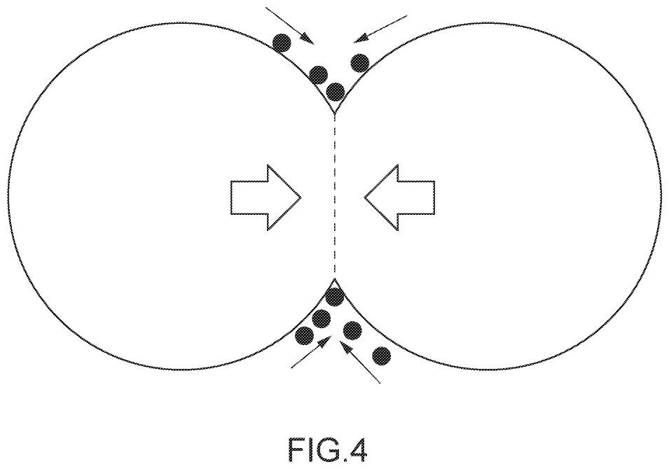

During the second sub-step S2, the ceramic material is further heated to a second temperature T2 and pressed to a set pressure P1. As the temperature and the pressure increase, sintering of the plate body starts, and the plate body formed by the ceramic material starts to shrink. The second temperature T2 may be between about 1,500 degrees Celsius and about 2,000 degrees Celsius. The second temperature T2 may be between about 1,700 degrees Celsius and about 1,900 degrees Celsius. The set pressure P1 may be between about 50 megapascals and about 100 megapascals. As will be appreciated by those of skill in the art in view of the present disclosure, the sintering may be a solid-phase sintering if the ceramic material is provided in the form of a powder. The sintering may be a liquid-phase sintering if the ceramic material is provided in the form of slurry. And the sintering may be both solid-phase and liquid-phase sintering may be carried out together. In the second sub-step S2, heat energy supplied may be used as a driving force for the movement of materials between particles, so the temperature increase during the second sub-step S2 may be slower than temperature increase during the first sub-step S1. As shown in FIG. 4, a sintering mechanism by movement of materials between particles along surfaces of the particles. Elements forming the particles may move to the grain boundary along the surface of the particles. Alternatively, materials may move through the interior of the particles.

With continuing reference to FIG. 3A, sintering may continue at the second temperature T2 and the set pressure P1 during the third sub-step S3. When the third sub-step S3 ends, the set pressure P1 ceases, and cooling may be accomplished during the fourth sub-step S4. Heating of the ceramic material may cease during the fourth sub-step S4. Cooling continues during the fifth sub-step S5, and the cooling rate during the fifth sub-step S5 increases such that the rate of cooling during the fifth sub-step S5 is greater than that of fourth sub-step S4 until the sintering process ends. While the sintering process shown in FIG. 3A can result in formation of a satisfactory heating block, the sintering process of FIG. 3A may also cause defects such as cracks, blisters, and swelling to develop within the heating block. Moreover, the sintering process of FIG. 3A may have relatively low yield due to the likelihood of the defects to develop within the heating block during the sintering process illustrated in FIG. 3A.

Referring to FIG. 3B, the step 120 (shown in FIG. 2) is shown according to an example having hot press sintering conditions differing from those shown in FIG. 3A. As shown in FIG. 3B, step 120 may be accomplished using a first sub-step S1′, a second sub-step S2′, and a third sub-step S3′. Step 120 may further be accomplished using a fourth sub-step S4′ and a fifth sub-step S5′. During the first sub-step S1′, the ceramic material provided to the plate mold and is heated to a first temperature T1. The first temperature T1 may be between about 800 degrees Celsius and about 1,000 degrees Celsius. During the first sub-step S1′, pressure may be also applied to the ceramic material.

In certain examples, both heating and pressing may occur during the first sub-step S1′, heating and pressing being coincident during the first sub-step S1′. The pressing may start after heating begins and prior to the ceramic material reaching the first temperature T1. The pressing may increase during the first sub-step S1′ to a set pressure P2. The set pressure P2 may be at least 25% higher than the set pressure P1. For example, the set pressure P2 may be between about 25% higher and about 50% than the set pressure P1. In accordance with certain examples, the set pressure P2 may be between about 75 megapascals and about 125 megapascals. As will be appreciated by those of skill in the art in view of the present disclosure, pressing to a set pressure P2 higher than the set pressure P1 renders the resulting ceramic material resulting from a sintering step including the sub-steps of FIG. 3B more dense than the ceramic material resulting from a sintering step including the sub-steps shown in FIG. 3A. As will also be appreciated by those of skill in the art in view of the present disclosure, the greater density of the ceramic material reduces (or eliminates) likelihood that defects may form in the heating block and/or may impart improved mechanical properties of the ceramic material, such as greater mechanical strength by way of non-limiting example.

During the second sub-step S2′, heating continues such that temperature of the ceramic material reaches the second temperature T2, sintering occurs, and the ceramic material starts to shrink. The second temperature T2 may be between about 1,500 degrees Celsius and about 2,000 degrees Celsius. The second temperature T2 may be between about 1,700 degrees Celsius and about 1,900 degrees Celsius. In certain examples, solid-phase sintering may occur during the second sub-step S2′, such as in examples where the ceramic material is provided in the form of a powder. In accordance with certain examples, liquid-phase sintering may occur during the second sub-step S2′, such as in examples where the ceramic material is provided in the form of slurry. It is also contemplated that, in accordance with certain examples, both solid phase and liquid phase sintering may occur during the second sub-step S2′. Heat energy supplied during the second sub-step S2′ may be used as a driving force for the movement of materials between particles, so it is contemplated that temperature increases during the second sub-step S2′ may be slower than the rate of temperature increase during the first sub-step S1′. It is further contemplated that pressure remain at the set pressure P2 during the second sub-step S2′.

During the third sub-step S3′, sintering continues at the second temperature T2 and the second pressure P2. In certain examples, the second temperature T2 may be between about 1,500 degrees Celsius and about 2,000 degrees Celsius. In accordance with certain examples, the second temperature T2 may be between about 1,700 degrees Celsius and about 1,900 degrees Celsius. It is also contemplated that, in accordance with certain examples, the third-sub-step may be carried out during a time interval that is greater than 36 hours. In this respect it is contemplated that the third sub-step S3′ may have a duration that is between about 36 hours and about 48 hours. The ceramic material may be maintained at the second temperature T2 during the full duration of the third sub-step S3′.

During the fourth sub-step S4′ the ceramic material is cooled, and heat may no longer be supplied to the ceramic material. The cooling rate during the fourth sub-step S4′ may be at least 3 times longer the cooling rate that occurs during the sub-step S4 (shown in FIG. 3A). In certain examples, the cooling rate during the fourth sub-step 4′ may be between about 1 degree Celsius per second and about 5 degrees Celsius per second. However, the pressure applied to the ceramic material may still be maintained at the set pressure P2 during the fourth sub-step S4′.

During the fifth sub-step S5′ the cooling rate increases relative to the cooling rate of the fourth sub-step S4′. As the cooling continues, the pressure may no longer be applied and the sintering process ends. In certain examples, pressing may cease prior to the completion of cooling of the ceramic material.

In the sintering process shown in FIG. 3B, when the heating begins, pressure may be applied together with the heating to the set pressure P2. In certain examples, the set pressure P2 shown in FIG. 3B may further be at least 25% higher than the set pressure P1 (shown in FIG. 3A). For example, the set pressure P2 may be between about 25% higher and about 50% higher than the set pressure P1. In accordance with certain examples, the cooling rate during the sub-step S4′ of FIG. 3B may be set to be at least 3 times longer than the cooling rate in the sub-step S4 (shown in FIG. 3A). For example, the cooling rate during the sub-step S4′ may between about 3 times longer and about 6 times longer that of the cooling rate of the sub-step S4. Advantageously, the comparatively longer cooling rate in the cooling sub-step S4′ shown in FIG. 3B relative to the cooling rate shown in sub-step S4 in FIG. 3A has the technical benefit of reducing residual stress in the sintered heating block body. Reducing residual stress in the sintered heating block body in turn reduces the likelihood that defects develop in the ceramic heating block, such as cracks, blisters, pores, and swelling that could otherwise occur in ceramic heating blocks manufactured using the sub-steps S1-S5 (shown in FIG. 3A).

During the cooling sub-step S4′, pressure may be maintained at the set pressure P2. Maintaining the pressure at the set pressure P2 may limit grain size in the resulting ceramic material forming the ceramic heating block relative to grain size of the ceramic material formed during the sintering process shown in FIG. 3A. The resulting relatively small grain size may in turn lead to the increase of specific surface area of particles, and as a consequence the particles may bond with greater numbers of neighboring particles relative to the bonding resultant from the sintering process shown in FIG. 3A. As a consequence, maintaining the pressure at the set pressure P2 during the first cooling sub-step S4′ therefore has the technical benefit of forming a relatively dense sintered body with more improved mechanical properties, e.g. high strength and high corrosive-resistance, relative to the ceramic material formed using the sintering process shown in FIG. 3A. For example, the grain size of the sintered body using the sintering process shown in FIG. 3A may be about 10 microns while grain size of the sintered body formed using the sintering process shown in FIG. 3B may be about 4 microns.

Referring now to FIG. 5, a cross-section of a heating block 200 formed using the sintering operation shown in FIG. 3B is shown. The heating block 200 is arranged within a semiconductor processing system 300 and includes a plate 210; a shaft 220; and an electrode 230. The heating block 200 also includes a heating element 240, a power rod 250, and an electrode rod 260. It is contemplated that the heating block 200 be formed using the method 200 (shown in FIG. 2). Specifically, a ceramic material is provided in the step 110 (shown in FIG. 2), the plate 210 is formed in the step 120 (shown in FIG. 2), the plate 210 is machined in the step 130 (shown in FIG. 2), the shaft 220 is bonded to the plate 210 in the step 140 (shown in FIG. 2), the power rod 250 and the electrode rod 260 are bonded to the plate 210 in the step 150 (shown in FIG. 2). The power rod 250 and the electrode rod 260 may be brazed to the plate 210 during the step 250; the electrode 230 and the heating element 240 may be embedded in the ceramic material during sintering in the step 120; and the sintering in the step 120 is accomplished using the sub-step S1′ (shown in FIG. 3B) through the sub-step S5′ (shown in FIG. 3B) of FIG. 3B.

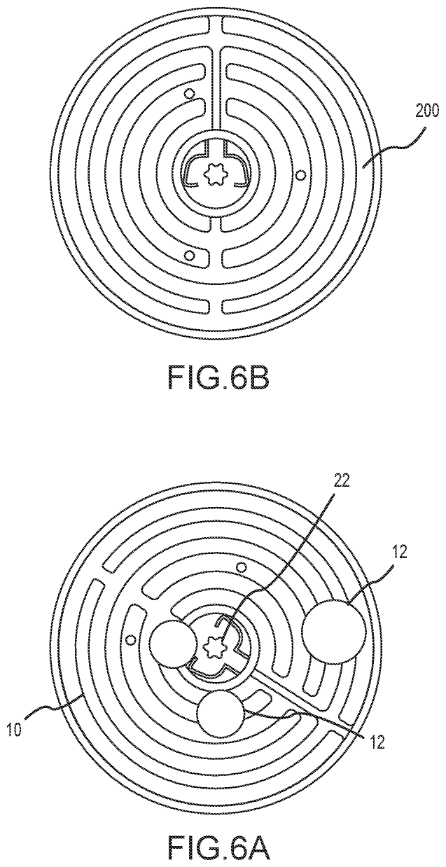

With reference to FIGS. 6A and 6B, heating blocks formed using the sintering operations of FIG. 3A and FIG. 3B are shown, As shown in FIG. 6A, a heating block 10 formed using the sub-step S1 (shown in FIG. 3A)-the sub-step S5 (shown in FIG. 3A) includes defects, e.g., swelling defects 12 and a blister defect 22. In contrast, the heating block 200 shown in FIG. 3B manufactured using the method 100 including sintering according to sub-step S1′ (shown in FIG. 3B)-sub-step S5′ (shown in FIG. 3B) has no defects. Therefore, a heating block with denser structure and no defects may be manufactured by the method 100 including a sintering operation step 220 having sub-step S1′-sub-step S5′ has a technical benefit of improving a reliability of the heating block. For instance, the inner structure of the heating block body may be both more dense that the heating block 12 and defect-free. Greater density in turn has the technical effect of improving a thermal conductivity within the heating block body and consequently film uniformity on a substrate supported on the upper surface of the heating block 200.

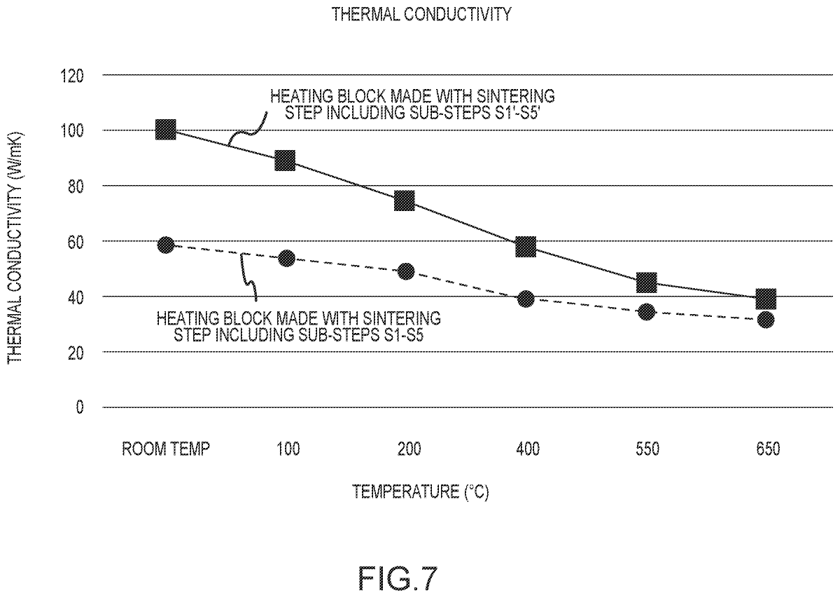

With reference to FIG. 7, a graph of thermal conductivity is shown for a heating block made with a sintering step including the sub-steps S1-S5 (shown in FIG. 3A), e.g., the heating block 10 (shown in FIG. 1), and a heating block made with a sintering step including the sub-steps S1′-S5′ (shown in FIG. 3B), e.g., the heating block 200 (shown in FIG. 5). As shown with a solid line having the solid squares, thermal conductivity of the a heating block made with the sintering step including the sub-steps S1′-S5′ is higher than thermal conductivity of the heating block made with the sintering step including the sub-steps S1-S5 shown with a dashed line having solid circles over a temperature range between room temperature and 650 degrees Celsius. Advantageously, the relatively high (e.g., improved) thermal conductivity of the heating block made using the sintering step including the sub-steps S1′-S5′ may prevent the unnecessary film from being deposited on the lower side (or backside) of the heating block. That is, as the thermal conductivity of the heating block improves, the temperature uniformity within the heating block may also improve. As will be appreciated by those of skill in art in view of the present disclosure, the relatively high thermal conductivity may reduce cold spots that could otherwise develop within the heating block body and cause film deposition on the lower surface of the heating block.

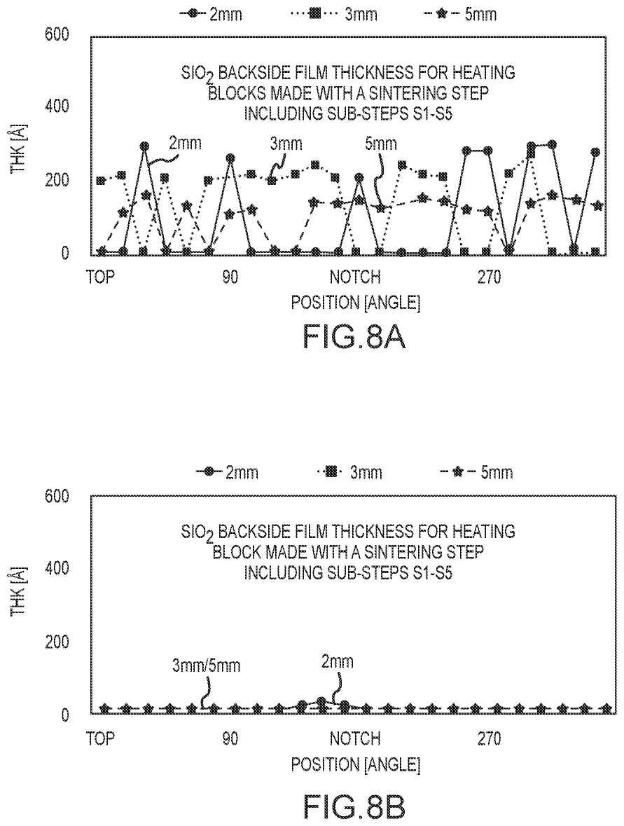

With reference to FIGS. 8A and 8B, thickness of a silicon oxide (SiO₂) backside film deposited on an edge portion (e.g., at 2 millimeters, 3 millimeters, and 5 millimeters inward from an outer edge of the heating blocks) is shown for heating blocks made using a sintering step including the sub-steps S1-S5 (shown in FIG. 3A) and a heating block made with a sintering step including the sub-steps S1′-S5′ (shown in FIG. 3B), respectively. As shown in FIG. 8A, during deposition of a silicon oxide layer onto a substrate seated on the heating block made using the sintering step including sub-steps S1-S5, silicon oxide film having a thickness between about 0 and 400 angstroms is deposited onto the lower surface of the heating block between 2 millimeters and 5 millimeters inward of the edge of the heating block. As shown in FIG. 8B, substantially no silicon oxide film is deposited onto the lower surface of the heating block made using the sintering step including the sub-steps S1′-S5′, e.g., the heating block 200 (shown in FIG. 5), between 2 millimeters and 5 millimeters inward of the edge of the heating block during deposition of a silicon oxide film onto a substrate supported on the upper surface of the heating block. Without being bound by a particular theory or mode of operation, it is believed that the thermal conductivity of the heating block discourages backside deposition of silicon oxide. As will be appreciated by those of skill in the art in view of the presenting disclosure, reducing (or eliminating) backside deposition can improve reliability of a semiconductor processing system including the heating block, e.g., the semiconductor processing system 300 (shown in FIG. 5), by limiting (or eliminating) the need to take the semiconductor processing system out of production to remove the backside silicon oxide deposition from the heating block.

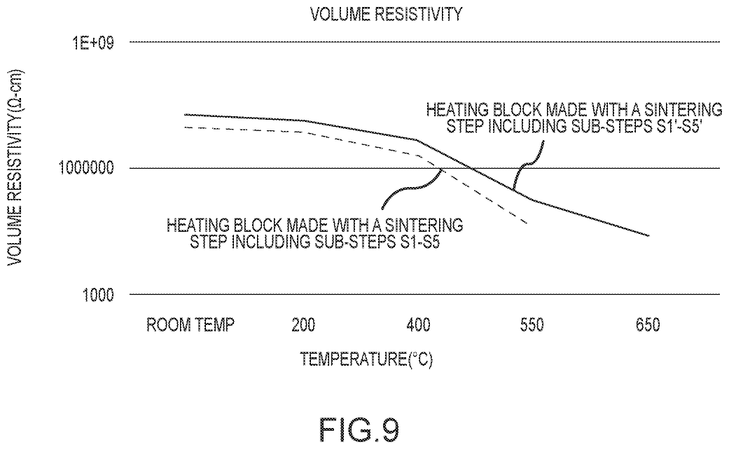

With reference to FIG. 9, a chart of volume resistivity versus temperature is shown for a heating block made with a sintering step including the sub-steps S1-S5, e.g., the heating block (shown in FIG. 1), for a heating block made with a sintering step including the sub-steps S1′-S5′, e.g., the heating block 200 (shown in FIG. 5), is shown. As shown with the solid line, volume resistivity of the heating block made with the sintering step including the sub-steps S1′-S5′ has greater volume resistivity between room temperature and 550 degrees Celsius than the heating block made using the sintering step including the sub-steps S1-S5. Moreover, volume resistivity is measurable in the heating block made with the sintering step including the sub-steps S1′-S5′ at 650 degrees Celsius while volume resistivity is not measurable in the heating block made with the sintering step including the sub-steps S1-S5 due to the overcurrent. As will be appreciated by those of skill in the art in view of the present disclosure, the sintering step including the sub-steps S1′-S5′ therefore provides a heating block with volume resistivity sufficient to provide electrostatic chucking capability over the same temperature range as heating blocks made using the sintering step including the sub-steps S1-S5 as well as at higher temperatures.

In sintering process for manufacturing a ceramic heating block according to the disclosure, the pressure is applied to the set pressure which is at least 25% higher than the existing condition from the heat supply step and maintained throughout the first cooling step. The first cooling sub-step is 3 times longer than the existing condition. Therefore, the residual stress in the heating block may be removed and the heating block body may be denser and more defect-resistant. The method of the disclosure may also enable uniform thermal conductivity within the heating block and prevent the backside film deposition. The disclosure may also enable a heating block to have a higher volume resistivity for better ESC function

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A method of manufacturing a heating block, comprising:
a first step of providing a ceramic material to a mold;
a second step of sintering the ceramic material and forming a plate;
a third step of machining the plate;
a fourth step of connecting a shaft to the plate; and
a fifth step of bonding rods to the plate.

2. The method of claim 1, wherein the second step of sintering the ceramic material and forming a plate further comprises:
a first sub-step of heating the ceramic material to a first temperature;
a second sub-step of further heating the ceramic material to a second temperature;
a third sub-step of maintaining the second temperature;
a fourth sub-step of cooling the plate to the first temperature; and
a fifth sub-step of cooling the plate to the second temperature,
wherein a pressure is applied to the ceramic material to a set pressure in the first sub-step and maintained throughout the fourth sub-step.

3. The method of claim 2, wherein the set pressure is between about 75 megapascals (10,900 pounds per square inch) and about 125 megapascals (about 18,000 pound square inch).

4. The method of claim 2, wherein the cooling rate in the fourth sub-step is between about 1 degree Celsius per second and about 5 degrees Celsius per second.

5. The method of claim 2, wherein the first temperature is between about 800 degrees Celsius (1,500 degrees Fahrenheit) and about 1,000 degrees Celsius (1,800 degrees Fahrenheit).

6. The method of claim 2, wherein the second temperature is between about 1,500 degrees Celsius (2,700 degrees Fahrenheit) and about 2,000 degrees Celsius (3,600 degrees Fahrenheit).

7. The method of claim 2, wherein the second temperature is maintained for more than 36 hours during the third sub-step.

8. The method of claim 1, wherein the ceramic material is at least one of aluminum nitride (AlN), boron nitride (BN), silicon nitride (SiN) and silicon carbide (SiC).

9. The method of claim 1, wherein the ceramic material comprises one or more additive, wherein the one or more additive comprises less than about 1% of the ceramic material by mass.

10. The method of claim 9, wherein the one or more additive comprises at least one of magnesium oxide (MgO) and aluminum magnesium oxide (Al₂MgO₄).

11. The method of claim 1, wherein the shaft comprises a cylinder with hollow inner space, and that the shaft supports the plate.

12. The method of claim 1, further comprising embedding a heating element and an electrode within the ceramic material.

13. The method of claim 12, wherein the third step of machining the plate imparts a flatness into the plate between about 20 microns (0.0008 inches) and about 50 microns (0.002 inches).

14. The method of claim 12, wherein the fifth step comprises:
connecting a power rod to the heating element; and
connecting the power rod to the electrode.

15. The method of claim 14, wherein the connecting is carried out by at least one of brazing, welding and soldering.

16. The method of claim 1, wherein the sintering is at least one of solid-phase sintering and liquid-phase sintering, or both.

17. A heating block fabricated using the method of claim 1.

18. The heating block of claim 17, further comprising:
a heating element embedded within the ceramic material forming the plate;
an electrode embedded within the ceramic material forming the plate;
a power rod electrically connected to the heating element and the electrode;
wherein the power rod is brazed to the heating element and the electrode; and
wherein the ceramic material comprises aluminum nitride (AlN) and an additive comprising comprises at least one of magnesium oxide (MgO) and aluminum magnesium oxide (Al₂MgO₄), the additive comprising less than about 1% of the ceramic material by weight.

19. A semiconductor processing system comprising a heating block manufactured using the method of claim 1.
